(19) United States
(12) Patent Application Publication
(10) Pub. No.: US 2024/0363520 A1
(43) Pub. Date: Oct. 31, 2024

(54) SELF-HEALING CAP FOR LIQUID METAL CONTAINMENT IN SOCKET APPLICATIONS

(71) Applicant: Intel Corporation, Santa Clara, CA (US)

(72) Inventors: Ziyin LIN, Chandler, AZ (US); Boer LIU, Tempe, AZ (US); Dingying David XU, Chandler, AZ (US); Karumbu MEYYAPPAN, Portland, OR (US)

(21) Appl. No.: 18/139,083

(22) Filed: Apr. 25, 2023

(51) Int. Cl. H01L 23/498; H01R 12/52

(52) U.S. Cl. CPC H01L 23/49894; H01L 23/49811; H01L 23/49833; H01R 12/52; H01L 24/16; H01L 24/32; H01L 24/73; H01L 2224/16225; H01L 2224/32225; H01L 2224/73204; H01R 4/2406; H01R 12/58; H05K 1/181; H05K 2201/10189; H05K 2201/10378

(57) ABSTRACT

Embodiments disclosed herein include a package substrate. In an embodiment, the package substrate comprises a substrate with a layer on the substrate. In an embodiment, the layer comprises a plurality of wells. In an embodiment, a liquid metal is in the plurality of wells. In an embodiment, a cap is on the layer to seal the plurality of wells, where the cap comprises a polymer, and fibers within the polymer.

### TECHNICAL FIELD

Embodiments of the present disclosure relate to electronic systems, and more particularly, to electronic packages with a liquid metal socket configuration that includes a self-healing cap for liquid metal containment.

### BACKGROUND

In electronic packaging, liquid metal interconnects are increasing in popularity. Liquid metal socket architectures allow for easy assembly and replacement of features. This is because there is no need to heat the system in order to reflow a solder connection between devices. Liquid metal architectures typically include a metal that is a liquid phase around room temperature. For example, gallium based alloys are an attractive option for liquid metal interconnect architectures.

Liquid metal carrier array (LMCA) interconnects use a cap layer that prevents the conductive liquid metal from leaking out during socket de-actuation. There are also electrical properties and moisture barrier requirements to improve device electrical performance and reliability. It is challenging to develop a material for the cap layer that meets all of the needs of the system.

To meet all of the design requirements, the cap thickness and structure is tightly controlled. For example, the minimal thickness of the cap is generally approximately 400 μm or more. The dimensions of the pin is also tightly controlled. For example, the pin diameter may be approximately 100 μm or less. Larger diameters result in the pull out of the liquid metal during de-actuation of the pins. Thin pin dimensions result in higher resistances, which is not desirable.

In one instance the cap layer may include a so-called self-healing polymer. A self-healing polymer has the advantage of being able to remove holes through the cap formed during the repeated insertion of pins through the cap. However, the dimensional stability of such cap layers is not good, and renders self-healing materials not suitable for many applications.

### BRIEF DESCRIPTION OF THE DRAWINGS

FIG. 1 is a perspective view illustration of an electronic system with a package substrate with a liquid metal carrier array (LMCA) that is configured to interface with a substrate with pins, in accordance with an embodiment.

FIG. 2A is a cross-sectional illustration of an electronic system with a socketing architecture that includes a hybrid cap layer over liquid metal wells, in accordance with an embodiment.

FIG. 2B is a cross-sectional illustration of a portion of a cap layer with woven fibers to form a fabric embedded in the polymer layer, in accordance with an embodiment.

FIG. 2C is a cross-sectional illustration of a portion of a cap layer with discrete fibers arranged in a woven pattern to form a fabric embedded in the polymer layer, in accordance with an embodiment.

FIG. 3A is a plan view illustration of a hybrid cap layer with holes formed through the cap layer, in accordance with an embodiment.

FIG. 3B is a plan view illustration of the hybrid cap layer with heat applied to heal the holes through the cap layer, in accordance with an embodiment.

FIG. 4 is a cross-sectional illustration of an electronic system with an LMCA that includes a hybrid cap layer with the liquid metal wells covered by a first portion of the hybrid cap layer and a second portion of the hybrid cap layer is over the LMCA, in accordance with an embodiment.

FIG. 5A is a cross-sectional illustration of an electronic system with an LMCA with a hybrid cap layer and a compressible layer on the board side.

FIG. 5B is a cross-sectional illustration of an electronic system with the compressible layer compressed between the LMCA and the board, in accordance with an embodiment.

FIG. 6 is a cross-sectional illustration of an electronic system with an LMCA that is covered by a cap layer that includes a moisture barrier, in accordance with an embodiment.

FIG. 7A is a cross-sectional illustration of an electronic system during assembly with a barrier on the package side and the board side, in accordance with an embodiment.

FIG. 7B is a cross-sectional illustration of the electronic system after coupling the package side to the board side so that the barriers are pressed against each other by a gasket, in accordance with an embodiment.

FIG. 8 is a schematic of a computing device built in accordance with an embodiment.

### EMBODIMENTS OF THE PRESENT DISCLOSURE

Described herein are electronic systems, and more particularly, electronic packages with a liquid metal socket configuration that includes a self-healing cap for liquid metal containment, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, liquid metal interconnect architectures, such as liquid metal socketing structures, are growing in importance to the electronics packaging industry. Generally, the liquid metal socketing structure includes a liquid metal carrier array (LMCA) that includes a plurality of wells. The wells may be filled with a liquid metal. As used herein, a liquid metal refers to a metallic structure that exhibits a liquid phase at temperatures around room temperature. For example, the liquid metal may be a liquid at temperatures down to approximately 0 degrees Celsius in some embodiments. A common liquid metal material is one that includes gallium. The gallium may be alloyed with other metallic constituents in some embodiments.

In order to confine the liquid metal to the wells of the LMCA, a capping layer (also referred to as simply a cap) is provided over the LMCA. The cap may have a material composition that allows for pins to be easily inserted into the wells. Further, the cap may prevent the extraction of liquid metal when the pin is removed from the LMCA. The cap may also provide a moisture barrier to mitigate oxidation of the liquid metal. Oxidation of the liquid metal may convert the liquid metal into a solid with a volume greater than a volume of the well. As such, the liquid metal may be extruded through the cap, which can lead to defects in the system.

Additionally, the cap should be a material that is amenable to repeated insertions and retractions of the socket pins. This allows for devices to be tested, replaced, or otherwise disassembled and reassembled. One potential material that enables repeated punctures of the cap may be a self-healing polymer. A self-healing polymer may refer to a material that can at least partially heal punctures through the cap. For example, application of heat may be used in order to allow the self-healing polymer to close the punctures. Self-healing polymers are promising, but existing self-healing polymers exhibit poor shape persistence through repeated healing processes. That is, while the punctures may be healed, the shape of the self-healing polymer may deform. Such deformation is not suitable for cap layers for liquid metal pin architectures.

Accordingly, embodiments disclosed herein include a self-healing polymer that is modified to form a hybrid or composite structure. The hybrid structure may include the presence of fibers (e.g., glass fibers) that are embedded within the polymer. In some embodiments, the glass fibers are woven together in order to form a fabric that is embedded within the polymer. One or more layers of the fabric may be provided within the self-healing polymer. The fabric provides enhanced dimensional stability in order to allow for multiple self-healing loops while maintaining the overall shape of the capping layer.

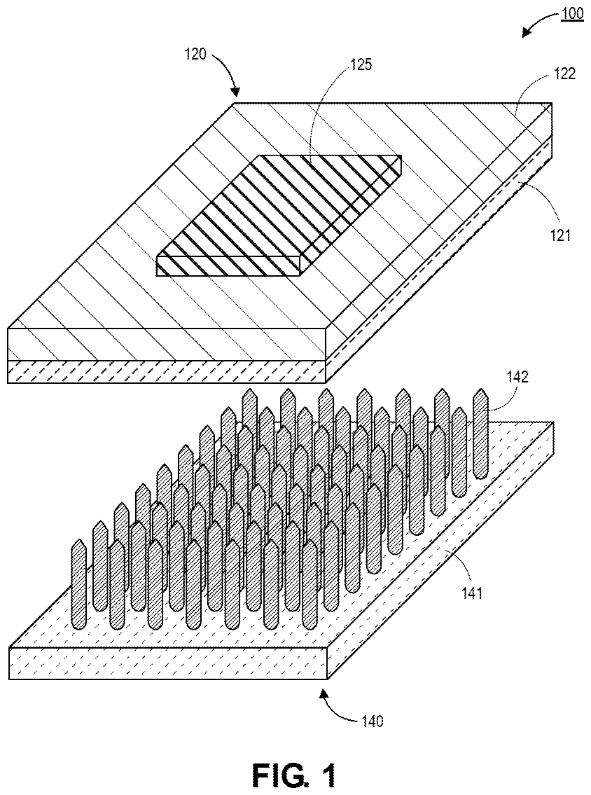

Referring now to FIG. 1, a perspective view illustration of an electronic system 100 is shown, in accordance with an embodiment. The electronic system 100 is shown with a first module 140 that is detached from a second module 120. The first module 140 may comprise a substrate 141, such as a board or the like, that includes a plurality of pins 142. The pins 142 may have diameters that are approximately 100 μm or larger. As used herein, “approximately” may refer to a range of values within ten percent of the stated value. For example, approximately 100 μm may refer to a range between 90 μm and 110 μm. Larger diameters are beneficial since a wider pin 142 may result in a reduction in the resistance along the pin 142. As such, electrical performance may be improved. In an embodiment, tips of the pins 142 may be pointed in order to aid the piercing of the capping layer (not shown in FIG. 1).

In an embodiment, the second module 120 may comprise a package substrate 122. The package substrate 122 may be an organic package substrate 122. The package substrate 122 may comprise a core (not shown). For example, the core may be an organic core, a glass core, or the like. In an embodiment, one or more dies 125 may be coupled to the package substrate 122.

In an embodiment, an LMCA 121 may be provided at a bottom of the package substrate 122. The LMCA 121 may be a material layer with a plurality of wells (not visible in FIG. 1). The wells may be filled with a liquid metal. For example, gallium or a gallium based alloy may be used to fill the wells. In the illustrated embodiment, the LMCA 121 is shown without a capping layer. Though, as will be described in greater detail below, a capping layer may be provided over the LMCA 121 in order to confine the liquid metal to the wells.

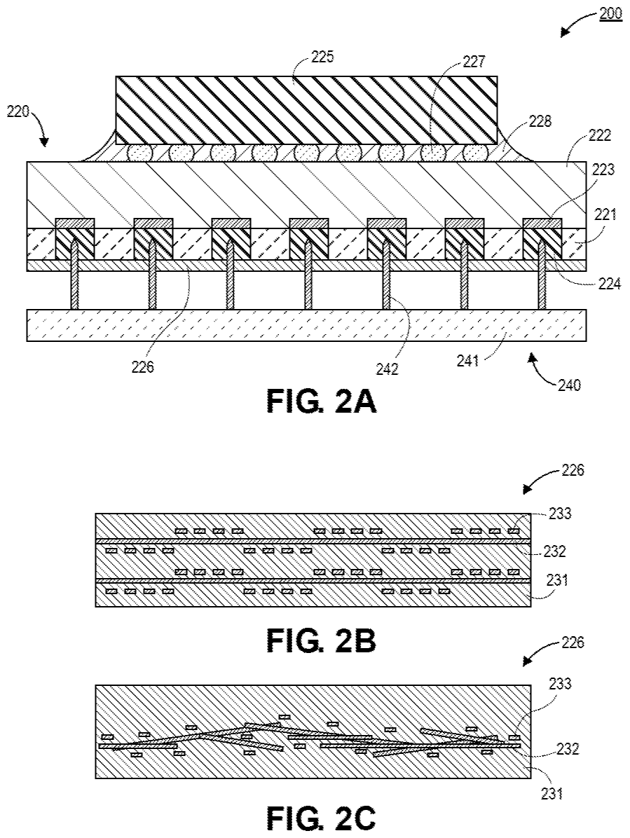

Referring now to FIG. 2A, a cross-sectional illustration of an electronic system 200 is shown, in accordance with an embodiment. In the embodiment shown in FIG. 2A, the first module 240 is electrically coupled to the second module 220. For example, pins 242 that extend up from the substrate 241 pierce the capping layer 226 and directly contact the liquid metal 224 that is provided in the wells of the LMCA 221. In an embodiment, the liquid metal 224 may be in direct contact with pads 223 that are provided in the package substrate 222. Electrical routing (not shown) within the package substrate 222 may couple the pads 223 to the overlying die 225. Interconnects 227 between the die 225 and the package substrate 222 may be any first level interconnect (FLI) architecture, such as solder balls or the like. The die 225 may be underfilled with an underfill 228 that surrounds the interconnects 227. In other embodiments, an overmold or an overmold and an underfill 228 may be provided around the die 225.

In an embodiment, the capping layer 226 may comprise a composite material system. For example, the capping layer 226 may comprise a polymer and fibers embedded in the polymer. In a particular embodiment, the polymer is a self-healing polymer. As used herein, a self-healing polymer refers to a polymer that is capable of healing deformations made in the polymer. For example, holes formed by pins 242 may be erased with a self-healing cycle. That is, the polymer may have a first state, and a hole may be formed into the polymer to form a second state. The self-healing process reverts the second state back to the first state (i.e., with sealed holes). In an embodiment, the self-healing process may involve applying heat to the polymer to enable the healing of damage. Reversible hydrogen bonding or ionic bonding may be one of the mechanisms for healing the polymer. Self-healing polymers may include any number of polymer materials. For example, the self-healing polymer may be a supramolecular polymer, such as one or more of poly(ethylene-co-methacrylate salt), sulfonated polytetrafluoroethylene, pressure sensitive adhesives with hydrogen bonding monomers, and nucleobase-containing acrylic copolymers. Referring now to FIG. 2B, a cross-sectional illustration of the capping layer 226 is shown, in accordance with an embodiment. As shown, the capping layer 226 may include a polymer matrix 231. The polymer matrix 231 may be a self-healing polymer, such as one of those described in greater detail above. The polymer matrix 231 may have a thickness that is approximately 100 μm or greater. In some embodiments, the polymer matrix 231 may have a thickness that is approximately 400 μm or greater. Though, a thinner polymer matrix 231 may also be used in some embodiments.

In an embodiment, the capping layer 226 may further comprise fibers 232 and 233 that are embedded in the polymer matrix 231. The fibers 232 are shown as having a length direction that is substantially parallel to the plane of FIG. 2B, and the fibers 233 are shown as having a length direction that is substantially orthogonal to the plane of FIG. 2B. In an embodiment, the fibers 233 and 232 may be provided in a woven pattern in order to form a well-defined fabric within the polymer matrix 231. For example, the structure shown in FIG. 2B includes two layers of the fabric of fibers 232 and 233. As shown, the two layers of the fabric (e.g., the two fibers 232) are substantially parallel to each other.

In an embodiment, the fibers 232 and 233 may be any suitable reinforcing fiber material. For example, the fibers 232 and 233 may include glass fibers. Though, other materials may also be used in some embodiments. In an embodiment, the fibers may have length dimensions that substantially match the dimensions of the capping layer 226. That is, continuous fibers may be provided across the width and/or length of the capping layer 226.

Referring now to FIG. 2C, a cross-sectional illustration of a capping layer 226 is shown in accordance with additional embodiments. In an embodiment, the capping layer 226 may include a polymer matrix 231, such as a self-healing polymer described in greater detail above. Additionally, reinforcement fibers 232 and 233 may be embedded within the polymer matrix 231. As shown, the fibers 232 are substantially within the plane of FIG. 2C, and the fibers 233 are substantially orthogonal to the plane of FIG. 2C. While fibers 232 and 233 are shown being orthogonal to each other, it is to be appreciated that the fibers 232 and 233 may have orientations that are randomly distributed through the polymer matrix 231 so that there is no directionality of the capping layer 226. That is, the fibers 232 and 233 may be randomly distributed in order to form a composite structure that has substantially isotropic material properties (e.g., modulus, etc.). That is, the fibers 232 and 233 may not be considered as being “woven” in some embodiments.

In an embodiment, the fibers 232 and 233 may have length dimensions that are smaller than the width and length dimensions of the capping layer 226. Additionally, the orientation of the fibers 232 may not be parallel with respect to the top and bottom surface of the polymer matrix 231. In the illustrated embodiment, the fibers 232 and 233 may be generally laid out to form a relatively planar fabric of fibers 232 and 233. While a single layer of the fabric is shown in FIG. 2C, it is to be appreciated that two or more layers of the fabric may be provided in some embodiments. The fibers 232 and 233 may be glass fibers, or any other suitable reinforcement material.

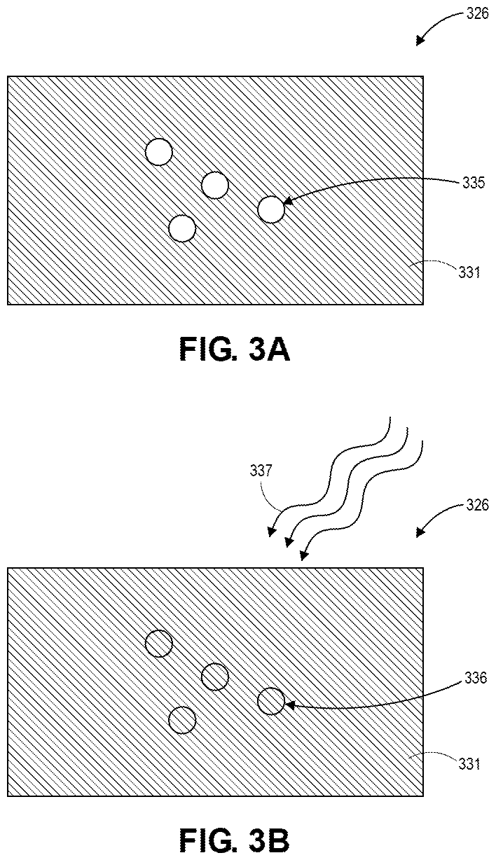

Referring now to FIGS. 3A and 3B, a self-healing cycle of a capping layer 326 is shown, in accordance with an embodiment. A polymer matrix 331 is shown in FIG. 3A. The polymer matrix 331 may be a self-healing polymer, such as those described in greater detail above. In the illustrated embodiment, fiber reinforcement is omitted for ease of illustration. Though, it is to be appreciated that fibers (e.g., woven fibers) may be provided as a fabric within the polymer matrix 331.

As shown in FIG. 3A, a plurality of holes 335 are formed through a thickness of the capping layer 326. The holes 335 may be formed by pins that are inserted through the capping layer 326. A plurality of holes 335 may be provided because the die module is coupled to several different boards, (e.g., for testing purposes, system replacements, or any other process). As can be appreciated, the attachment of the die module to different boards will not result in the pins being perfectly aligned with previous pins, and the holes 335 may be offset from each other. While four holes 335 are shown in FIG. 3A, it is to be appreciated that any number of holes 335 (e.g., one or more holes 335) may be provided before a self-healing process is implemented, in accordance with an embodiment.

Referring now to FIG. 3B, a plan view illustration of the capping layer 326 after a self-healing process is shown, in accordance with an embodiment. The self-healing process may be initiated by applying heat (as indicated with arrows 337) to the capping layer 326. The thermal energy may allow for the polymer matrix 331 to reflow or otherwise re-orient the polymer strands to initiate the filling of the holes 335 to form filled holes 336. The self-healing process may sometimes be referred to as a reversible hydrogen bonding system in some embodiments. Though, it is to be appreciated that any reversible bonding system may be used in accordance with embodiments described herein.

Resealing the holes 335 provides several benefits. One such benefit is that there are no pathways for the liquid metal to seep out of the wells in the LMCA. Additionally, the sealed holes 336 prevent oxygen and moisture from reaching the liquid metal, and prevents oxidation of the liquid metal. Accordingly, reliability of the socketing system is improved while allowing for simpler testing, assembly, and replacement processes.

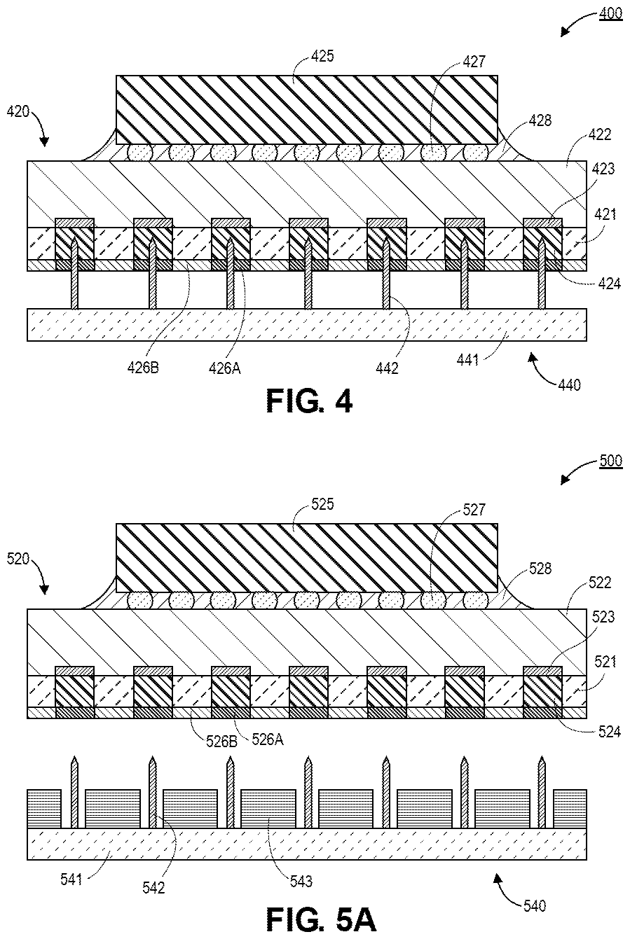

Referring now to FIG. 4, a cross-sectional illustration of an electronic system 400 is shown, in accordance with an embodiment. In the embodiment shown in FIG. 4, the first module 440 is electrically coupled to the second module 420. For example, pins 442 that extend up from the substrate 441 pierce the capping layer 426 and directly contact the liquid metal 424 that is provided in the wells of the LMCA 421. In an embodiment, the liquid metal 424 may be in direct contact with pads 423 that are provided in the package substrate 422. Electrical routing (not shown) within the package substrate 422 may couple the pads 423 to the overlying die 425. Interconnects 427 between the die 425 and the package substrate 422 may be any FLI architecture, such as solder balls or the like. The die 425 may be underfilled with an underfill 428 that surrounds the interconnects 427. In other embodiments, an overmold or an overmold and an underfill 428 may be provided around the die 425.

In an embodiment, the capping layer 426 may comprise first regions 426A and second regions 426B. The first regions 426A may span across the openings of the wells in the LMCA 421, and the second regions 426B may be provided between the first regions 426A. In an embodiment, the first regions 426A may have a different structure than the second regions 426B. For example, the first regions 426A may be a hybrid capping layer 426A, and the second regions 426B may only include the polymer matrix. The polymer matrix for both the first regions 426A and the second regions 426B may be self-healing polymer material. Though in other embodiments, only the first regions 426A include a self-healing polymer matrix.

In an embodiment, the first regions 426A of the capping layer 426 may comprise a polymer and fibers embedded in the polymer. As noted above, the polymer is a self-healing polymer. That is, the polymer may have a first state, and a hole may be formed into the polymer to form a second state. The self-healing process reverts the second state back to the first state (i.e., with sealed holes). In an embodiment, the self-healing process may involve applying heat to the polymer to enable the healing of damage. Reversible hydrogen bonding may be one of the mechanisms for healing the polymer. Self-healing polymers may include any number of polymer materials, such as those described in greater detail above.

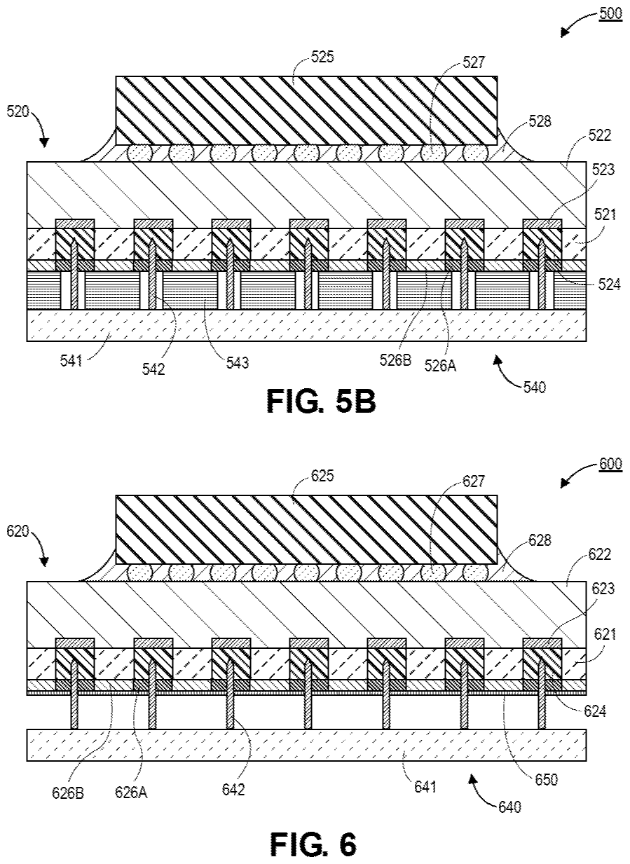

Referring now to FIG. 5A a cross-sectional illustration of an electronic system 500 during assembly is shown, in accordance with an embodiment. As shown, the first module 540 is prepared to be attached to the second module 520. The first module 540 may comprise a substrate 541, such as a board. Pins 542 may extend out from the substrate 541. The pins 542 may be provided between compressible members 543. The compressible members 543 may be used in order to improve moisture and air isolation of the liquid metal 524 when the first module 540 is attached to the second module 520.

In an embodiment, the second module 520 may comprise a package substrate 522. The package substrate 522 may include an LMCA 521 on a surface facing the first module 540. In an embodiment, the LMCA 521 may comprise wells that are filled with a liquid metal 524, such as gallium or a gallium based alloy. In an embodiment, the liquid metal 524 is in direct contact with pads 523 on the package substrate 522. Electrical routing through the package substrate 522 (not shown) may provide electrical coupling between the pads 523 and the overlying die 525. The die 525 may be coupled to the package substrate 522 by interconnects 527 that may be any suitable FLI architecture. An underfill 528 or a molding compound may be provided around the die 525.

In an embodiment, a capping layer 526 may be provided over the LMCA 521 in order to confine the liquid metal 524. In the embodiments shown in FIG. 5A, the capping layer 526 includes first regions 526A and second regions 526B. Though, it is to be appreciated that embodiments may include a capping layer 526 with a single composition across the entire LMCA 521. The first region 526A of the capping layer 526 may include a composite self-healing polymer with fiber reinforcement (e.g., a glass fiber fabric, or the like). The self-healing polymer may be similar to any of the self-healing polymers described in greater detail above.

Referring now to FIG. 5B, a cross-sectional illustration of the electronic system 500 after the first module 540 is coupled to the second module 520 is shown, in accordance with an embodiment. As shown, the pins 542 may pierce the capping layer 526 (e.g., the first regions 526A) in order to directly contact the liquid metal 524 within the wells of the LMCA 521. In an embodiment, the compressible members 543 may also be compressed between the capping layer 526 and the substrate 541. For example, the compressible members 543 may be a polymer, a rubber, a gasket material, or any other suitable compressible material. When the first module 540 is coupled to the second module 520 (e.g., with an attachment mechanism that is out of the plane of FIG. 5B), the compressible members 543 may provide an outward force that pushes against the capping layer 526 and the substrate 541. This provides a seal around the first regions 526A and aids in the prevention of moisture and air reaching the liquid metal 524.

Referring now to FIG. 6, a cross-sectional illustration of an electronic system 600 with a first module 640 attached to a second module 620 is shown, in accordance with an embodiment. The first module 640 may comprise a substrate 641, such as a board. Pins 642 may extend out from the substrate 641. The pins 642 may penetrate through a capping layer 626 and a moisture barrier 650.

In an embodiment, the second module 620 may comprise a package substrate 622. The package substrate 622 may include an LMCA 621 on a surface facing the first module 640. In an embodiment, the LMCA 621 may comprise wells that are filled with a liquid metal 624, such as gallium or a gallium based alloy. In an embodiment, the liquid metal 624 is in direct contact with pads 623 on the package substrate 622. Electrical routing through the package substrate 622 (not shown) may provide electrical coupling between the pads 623 and the overlying die 625. The die 625 may be coupled to the package substrate 622 by interconnects 627 that may be any suitable FLI architecture. An underfill 628 or a molding compound may be provided around the die 625.

In an embodiment, the capping layer 626 is provided over the LMCA 621 in order to confine the liquid metal 624. In the embodiments shown in FIG. 6, the capping layer 626 includes first regions 626A and second regions 626B. Though, it is to be appreciated that embodiments may include a capping layer 626 with a single composition across the entire LMCA 621. The first region 626A of the capping layer 626 may include a composite self-healing polymer with fiber reinforcement (e.g., a glass fiber fabric, or the like). The self-healing polymer may be similar to any of the self-healing polymers described in greater detail above.

In an embodiment, the capping layer 626 may be covered by a barrier layer 650. The barrier layer 650 may be a material that has better moisture or air resistance than the capping layer 626. For example, the capping layer 626 may be a polymer, an oxide, a nitride, or any other suitable material layer. A thickness of the barrier layer 650 may be thinner than a thickness of the capping layer 626. The barrier layer 650 may be self-healing in some embodiments. Though, in other embodiments, the barrier layer 650 may not be self-healing.

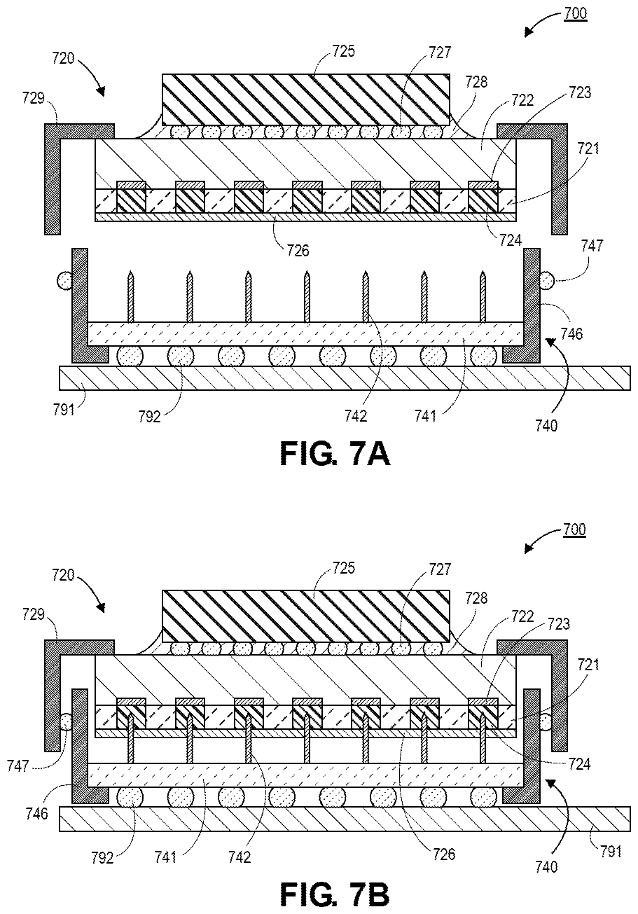

Referring now to FIGS. 7A and 7B, cross-sectional illustrations of the assembly of an electronic system 700 is shown, in accordance with an embodiment. As shown in FIG. 7A, the electronic 700 may comprise a first module 740 that is mounted to a second module 720. The first module 740 may comprise a substrate 741, such as a board or the like. The substrate 741 may be mounted to a motherboard 791 by interconnects 792 or the like. Pins 742 may extend up from the substrate 741. In an embodiment, the first module 740 may comprise a barrier 746 around a perimeter of the substrate 741. A gasket 747 or the like may be provided adjacent to an outer surface of the barrier 746.

In an embodiment, the second module 720 may be similar to any of the second modules described in greater detail above. For example, the second module 720 may comprise a package substrate 722 with an LMCA 721 over a surface of the package substrate 722 facing the first module 740. The LMCA 721 may include wells filled with a liquid metal 724. The liquid metal 724 may be in direct contact with pads 723. Die 725 may be coupled to the package substrate 722 through interconnects 727. An underfill 728 or mold layer may surround the die 725. In an embodiment, a capping layer 726 is provided over the LMCA 721. The capping layer 726 may comprise a composite material including a self-healing polymer with embedded fibers, similar to any of the capping layers described in greater detail above. In an embodiment, a barrier 729 may be provided around a perimeter of the package substrate 722.

Referring now to FIG. 7B, a cross-sectional illustration of the electronic system 700 with the first module 740 coupled to the second module 720 is shown, in accordance with an embodiment. As shown, the pins 742 extend through the capping layer 726 to contact the liquid metal 724. In an embodiment, the barrier 729 is brought down around the barrier 746. The gasket 747 between the two can provide a seal that is moisture tight and/or air tight. As such, the possibility of oxidizing the liquid metal 724 is reduced.

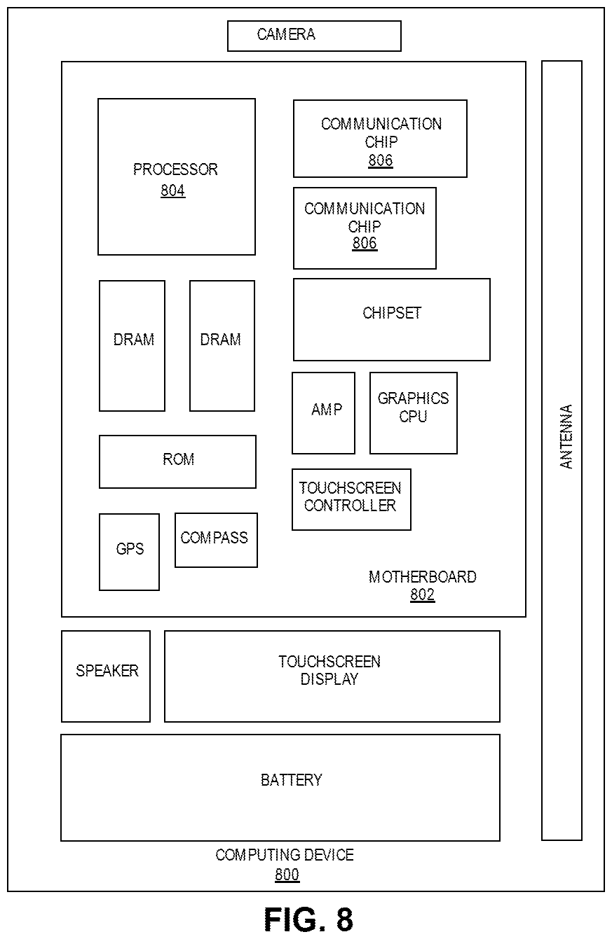

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic system with a liquid metal socket structure that includes a composite capping layer with a self-healing polymer and reinforcement fibers, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic system with a liquid metal socket structure that includes a composite capping layer with a self-healing polymer and reinforcement fibers, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a substrate; a layer on the substrate, wherein the layer comprises a plurality of wells; liquid metal in the plurality of wells; and a cap on the layer to seal the plurality of wells, wherein the cap comprises: a polymer; and fibers within the polymer.

Example 2: the package substrate of Example 1, wherein the fibers are woven into a fabric that is embedded in the polymer.

Example 3: the package substrate of Example 2, further comprising a plurality of fabric layers embedded in the polymer.

Example 4: the package substrate of Example 1, wherein the fibers are randomly distributed throughout the polymer.

Example 5: the package substrate of Example 4, wherein the polymer includes a reversible hydrogen bonding system or an ionic bonding system.

Example 6: the package substrate of Example 4, wherein the polymer is a supramolecular polymer.

Example 7: the package substrate of Example 6, wherein the supramolecular polymer comprises one or more of poly(ethylene-co-methacrylate salt), sulfonated polytetrafluoroethylene, pressure sensitive adhesives with hydrogen bonding monomers, and nucleobase-containing acrylic copolymers.

Example 8: the package substrate of Examples 1-7, wherein the fibers comprise glass fibers.

Example 9: the package substrate of Examples 1-8, wherein the liquid metal comprises gallium.

Example 10: a socket system, comprising: a first substrate; a layer on the first substrate, wherein a well is formed through the layer; a liquid metal in the well; and a cap that spans across an opening of the well, wherein the cap comprises: a polymer; and fibers embedded in the polymer; a second substrate; and a pin extending from the second substrate, wherein the pin is inserted through the cap and contacts the liquid metal in the well.

Example 11: the socket system of Example 10, wherein the pin has a width that is approximately 100 μm or greater.

Example 12: the socket system of Example 10 or Example 11, further comprising a layer between the first substrate and the second substrate, wherein the layer is compressed when the pin is inserted through the cap.

Example 13: the socket system of Examples 10-12, wherein the polymer is a self-healing polymer.

Example 14: the socket system of Examples 10-13, wherein the fibers are woven into a fabric that is embedded within the polymer.

Example 15: the socket system of Examples 10-14, wherein the fibers are glass fibers.

Example 16: the socket system of Examples 10-15, wherein the liquid metal comprises gallium.

Example 17: the socket system of Examples 10-16, wherein the first substrate is a package substrate.

Example 18: an electronic system, comprising: a board; a package substrate coupled to the board with socket interconnects, wherein the socket interconnects comprise: a liquid metal well confined by a cap, wherein the cap comprises: a self-healing polymer; and fibers embedded in the self-healing polymer; and a pin that extends from the board, passes through the cap, and contacts liquid metal in the liquid metal well; and a die coupled to the package substrate.

Example 19: the electronic system of Example 18, wherein the fibers are woven into a fabric embedded in the self-healing polymer, or wherein the fibers are randomly distributed through the self-healing polymer.

Example 20: the electronic system of Example 18 or Example 19, wherein the electronic system is part of a personal computer, a server, a mobile device, a tablet, or an automobile.

What is claimed is:

1. A package substrate, comprising:
a substrate;
a layer on the substrate, wherein the layer comprises a plurality of wells;
liquid metal in the plurality of wells; and
a cap on the layer to seal the plurality of wells, wherein the cap comprises:
a polymer; and
fibers within the polymer.

2. The package substrate of claim 1, wherein the fibers are woven into a fabric that is embedded in the polymer.

3. The package substrate of claim 2, further comprising a plurality of fabric layers embedded in the polymer.

4. The package substrate of claim 1, wherein the fibers are randomly distributed throughout the polymer.

5. The package substrate of claim 4, wherein the polymer includes a reversible hydrogen bonding system or an ionic bonding system.

6. The package substrate of claim 4, wherein the polymer is a supramolecular polymer.

7. The package substrate of claim 6, wherein the supramolecular polymer comprises one or more of poly(ethylene-co-methacrylate salt), sulfonated polytetrafluoroethylene, pressure sensitive adhesives with hydrogen bonding monomers, and nucleobase-containing acrylic copolymers.

8. The package substrate of claim 1, wherein the fibers comprise glass fibers.

9. The package substrate of claim 1, wherein the liquid metal comprises gallium.

10. A socket system, comprising:
a first substrate;
a layer on the first substrate, wherein a well is formed through the layer;
a liquid metal in the well; and
a cap that spans across an opening of the well, wherein the cap comprises:
a polymer; and
fibers embedded in the polymer;
a second substrate; and
a pin extending from the second substrate, wherein the pin is inserted through the cap and contacts the liquid metal in the well.

11. The socket system of claim 10, wherein the pin has a width that is approximately 100 μm or greater.

12. The socket system of claim 10, further comprising a layer between the first substrate and the second substrate, wherein the layer is compressed when the pin is inserted through the cap.

13. The socket system of claim 10, wherein the polymer is a self-healing polymer.

14. The socket system of claim 10, wherein the fibers are woven into a fabric that is embedded within the polymer.

15. The socket system of claim 10, wherein the fibers are glass fibers.

16. The socket system of claim 10, wherein the liquid metal comprises gallium.

17. The socket system of claim 10, wherein the first substrate is a package substrate.

18. An electronic system, comprising:
a board;
a package substrate coupled to the board with socket interconnects, wherein the socket interconnects comprise:
a liquid metal well confined by a cap, wherein the cap comprises:
a self-healing polymer; and
fibers embedded in the self-healing polymer; and
a pin that extends from the board, passes through the cap, and contacts liquid metal in the liquid metal well; and
a die coupled to the package substrate.

19. The electronic system of claim 18, wherein the fibers are woven into a fabric embedded in the self-healing polymer, or wherein the fibers are randomly distributed through the self-healing polymer.

20. The electronic system of claim 18, wherein the electronic system is part of a personal computer, a server, a mobile device, a tablet, or an automobile.
